(19) United States
(12) Patent Application Publication
(10) Pub. No.: US 2008/0065943 A1
(43) Pub. Date: Mar. 13, 2008

(54) Method and system for using data from a failed CRC block to determine retransmission of data packets

(76) Inventor: Louis Botha, San Diego, CA (US)

Correspondence Address: MCANDREWS HELD & MALLOY, LTD, 500 WEST MADISON STREET, SUITE 3400, CHICAGO, IL, 60661, US

(21) Appl. No.: 11/520,251

(22) Filed: Sep. 13, 2006

(51) Int. Cl. H04L 1/18; H03M 13/00

(52) U.S. Cl. 714/748; 714/776

(57) ABSTRACT

Certain aspects of a method and system for using data from a failed cyclic redundancy check (CRC) block to determine whether retransmission of data packets should occur are disclosed. Aspects of one method may include determining a sequence number of a received packet with a failed cyclic redundancy check (CRC). A request may be communicated to a sending station to resend the received packet based on the determined sequence number. The received packet with a failed CRC may be detected, if an error flag is set in the received packet. A negative acknowledgement (NACK) packet may be communicated to request the sending station to resend the received packet.

### CROSS-REFERENCE TO RELATED APPLICATIONS/INCORPORATION BY REFERENCE

None

### FIELD OF THE INVENTION

Certain embodiments of the invention relate to wireless communication systems. More specifically, certain embodiments of the invention relate to a method and system for using data from a failed cyclic redundancy check (CRC) block to determine retransmission of data packets.

### BACKGROUND OF THE INVENTION

A transmitter may transmit information over a channel or medium and the transmitted information may be received without alteration and processed by a receiver. However, a transmission medium or channel is constantly subjected to impairments such as noise and interference. Consequently, when a transmitter transmits information, a receiver may not receive the information in an identical manner in which it was transmitted. This may be due to impairments in a channel that may typically introduce errors in the transmitted information. A transmitter may code the data in such a manner that error introduced during transmission may be detected and/or corrected during reception.

Cyclic redundancy is one method, which may be utilized to code information for transmission so that at least some errors may be detected and/or corrected. A cyclic redundancy check (CRC) may be computed for a group or block of bits referred to as frames. The computed CRC may then be appended to each frame for which a CRC is computed and the frame with the CRC may be transmitted. The appended CRC may be referred to as a frame check sequence (FCS).

On the receive side, the frame check sequence may be extracted from the received information and a CRC may be computed for the received information. This calculated CRC of the received frame may then be compared with the frame check sequence and if there is a mismatch, then the received frame may be in error.

CRC utilizes very little overhead and may be easily implemented. Many conventional devices currently use cyclic redundancy check (CRC) to determine if there is an error in information that has been received from a transmitting entity. For example, a receiver may be enabled to determine a CRC on frames in a payload of a received packet. The computed CRC may be compared with a frame check sequence to determine whether the frame is in error. If the frame is determined to be in error and the error may be corrected, then the frame may be acknowledged. If the frame is in error and the error may not be corrected, then the receiver may send an indication or a signal such as a negative acknowledgement, thereby causing the packet to be retransmitted by the transmitter.

In certain instances, for example, when a very large file is transmitted and received for processing, there may be a possibility that when a CRC is computed on a corresponding received frame, the computed CRC may pass even though there may be multiple bit errors in the receive frame. This may be referred to as a false CRC pass. These types of false CRC pass indicators may be destructive in a large program or image that is being transferred.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A method and/or system for using data from a failed cyclic redundancy check (CRC) block to determine retransmission of data packets, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of a sending and receiving station that may be enabled to send and receive broadcasts and cellular communications, in accordance with an embodiment of the invention.

FIG. 2 illustrates an exemplary radio link packet structure in accordance with an embodiment of the invention.

FIG. 3 illustrates an exemplary radio link packet header structure, in accordance with an embodiment of the invention.

FIG. 4 is a flowchart illustrating exemplary steps for using data from a failed cyclic redundancy check (CRC) block to determine retransmission of data packets, in accordance with an embodiment of the invention.

### DETAILED DESCRIPTION OF THE INVENTION

Certain embodiments of the invention may be found in a method and system for using data from a failed cyclic redundancy check (CRC) block to determine whether retransmission of data packets should be performed. Certain aspects of the invention may comprise determining a sequence number of a received packet with a failed cyclic redundancy check (CRC). A request may be communicated to a sending station to resend the received packet based on the determined sequence number. The received packet with a failed CRC may be detected, if an error flag is set in the received packet. A negative acknowledgement (NACK) packet may be communicated to request the sending station to resend the received packet.

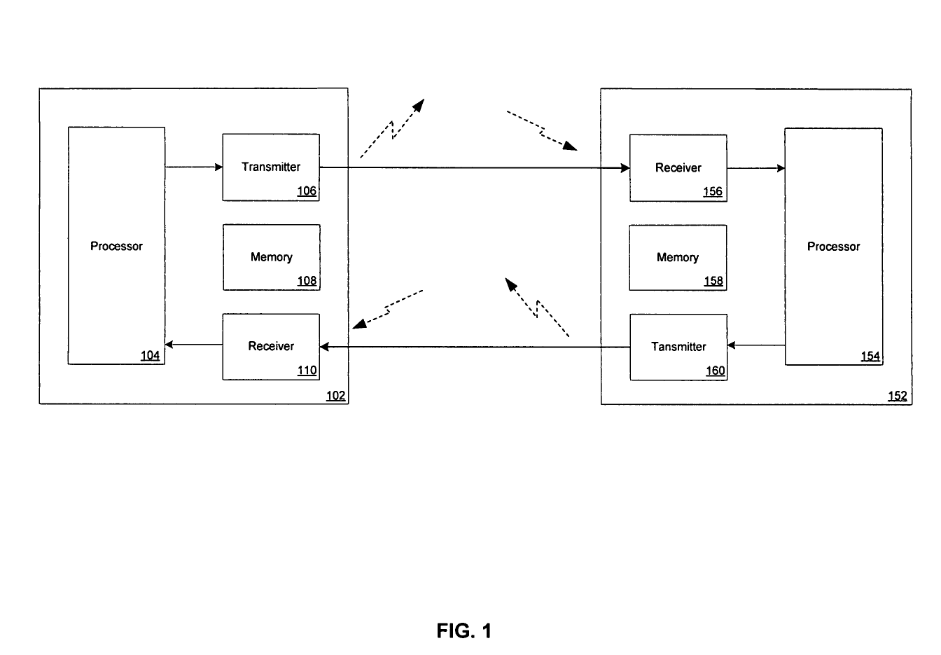

FIG. 1 is a block diagram of a sending and receiving station that may be enabled to send and receive broadcasts and cellular communications, in accordance with an embodiment of the invention. Referring to FIG. 1, there is shown a sending station 102 and a receiving station 152. The sending station 102 may comprise a processor 104, a transmitter 106, a memory 108 and a receiver 110. The receiving station 152 may comprise a processor 154, a transmitter 156, a memory 158 and a receiver 160.

The processor 104 may comprise, for example, an RF integrated circuit (RFIC) or RF front end (RFFE). The processor 104 may be enabled to handle processing of VHF/UHF broadcast channel and/or a cellular channel. The transmitter 106 may comprise suitable logic, circuitry and/or code that may be enabled to modulate an information signal to a suitable carrier frequency and transmit the information signal to a receiving station, for example, receiving station 152. The receiver 110 may comprise suitable logic, circuitry and/or code that may be enabled to receive an information signal and down-convert the received information signal into intermediate frequency (IF) signals. The memory 108 may comprise suitable logic, circuitry and/or code that may be enabled to store and transfer data to the processor 104. The processor 104 may be enabled to receive information from the receiver 110 and decode the received information. During data transmission, the processor 104 may be enabled to code information to be transmitted using a particular coding algorithm. The sending station 102 may be a wireless station or a wired station. The sending station 102 may be enabled to transmit and receive data packets or information signals via a wired medium or a wireless medium.

The processor 154 may comprise, for example, an RF integrated circuit (RFIC) or RF front end (RFFE). In this regard, the processor 154 may comprise at least one receiver front end (RFE) circuit. In an embodiment of the invention, a single RFIC may comprise a plurality of RFE processing circuits, each of which may be enabled to process a particular cellular channel. Accordingly, a single RFIC comprising a plurality of cellular RFE processing circuits may be enabled to handle a plurality of cellular channels.

The processor 154 may be enabled to compute the CRC value of the received data packets. A CRC may be computed for a group or block of bits referred to as frames. The computed CRC may then be appended to each frame for which a CRC is computed and the frame with the CRC may be transmitted. The appended CRC may be referred to as a frame check sequence (FCS).

The transmitter 156 may comprise suitable logic, circuitry and/or code that may be enabled to modulate an information signal to a suitable carrier frequency and transmit the information signal to a base station, for example, sending station 102. The receiver 160 may comprise suitable logic, circuitry and/or code that may be enabled to receive an information signal from a base station, for example, a sending station 102 and down-convert the received information signal into intermediate frequency (IF) signals. The memory 158 may comprise suitable logic, circuitry and/or code that may be enabled to store and transfer data to the processor 154. The receiving station 152 may be a wireless station or a wired station. The receiving station 152 may be enabled to transmit and receive data packets or information signals via a wired medium or a wireless medium.

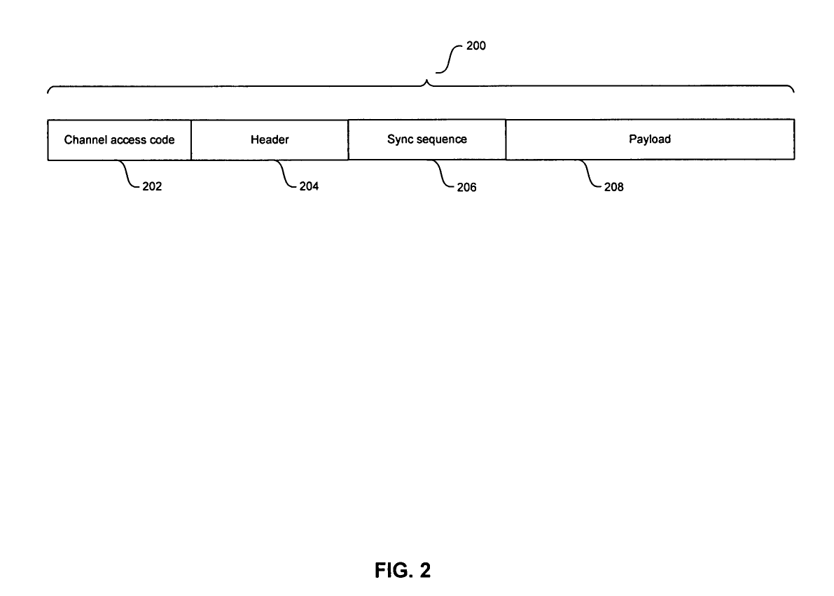

FIG. 2 illustrates an exemplary radio link packet structure, in accordance with an embodiment of the invention. Referring to FIG. 2, a general packet structure format for an exemplary radio link packet 200 may comprise a channel access code 202, a header 204, a synchronization (sync) sequence 206, and a payload 208. In this regard, a portion of the radio link packet 200 may also be referred to as a field. The channel access code 202 may comprise a portion of the radio link packet 200 that may be utilized to identify packets on a particular physical channel and/or to exclude or ignore packets on a different physical channel that may be using the same radio frequency (RF) carrier. The packets that are transmitted in the same physical channel may have a similar access code, for example. In a receiving station 152, a sliding correlator may be utilized to correlate at least a portion of the contents of the channel access code 202 and the sliding correlator may trigger to indicate that a channel access code match has occurred when, for example, a threshold level is exceeded.

The header 204 may comprise a portion of the radio link packet 200 that may be utilized for indicating to a receiving station 152 when a particular packet is addressed to that receiving station 152, the type of packet, a sequential numbering of the packet to order the data packet stream, and/or the manner in which the packet may be routed internally to that receiving station 152, for example.

The sync sequence 206 may comprise a portion of the radio link packet 200 that may be utilized to synchronize the contents of the payload 208. This synchronization may be necessary for cases when the payload 208 may be modulated utilizing a different scheme than for other portions of the radio link packet 200. The payload 208 may comprise a portion of the radio link packet 200 that may be utilized to transport user information.

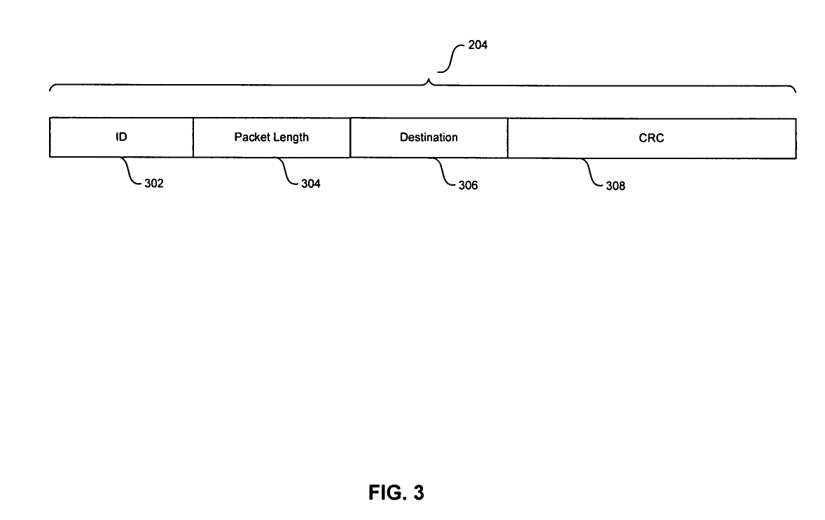

FIG. 3 illustrates an exemplary radio link packet header structure, in accordance with an embodiment of the invention. The packet header 204 may comprise an identification (ID) field 302, packet length field 304, destination information 306, and cyclic redundancy check (CRC) validation information 308. The ID field 302 may comprise control information that may specify the origin of the packet to a receiving station 152. For example, the ID field 302 may specify a sending station 102 that may have transmitted the packet. The packet length field 304 may provide information regarding the length of a transmitted packet. The destination field 306 may comprise the address of a particular receiving station 152. The CRC field 308 may comprise data associated with a CRC data validation calculation. The CRC field 308 may be utilized for detecting data transmission errors. The transmitted packets may be divided into predetermined lengths that may be divided by a fixed divisor. The remainder number may be appended and transmitted with the packet. When the packet is received, the remainder may be recalculated and may be compared to the transmitted remainder. If the calculated remainder does not match with the appended remainder value, an error may be detected and an error flag may be set indicating a failed CRC. The CRC field 308 may comprise an error flag that may be set when a failed CRC is detected.

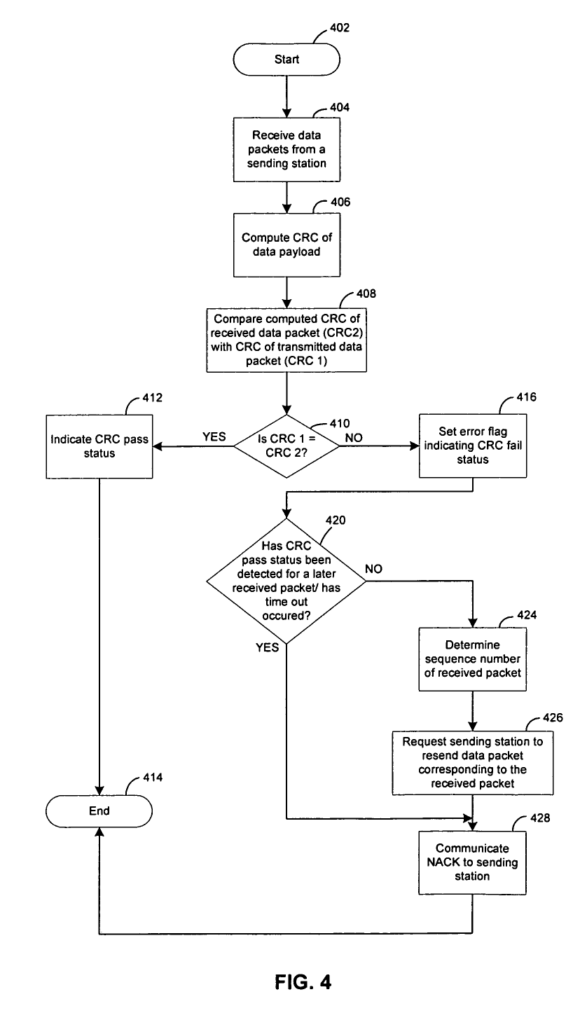

FIG. 4 is a flowchart illustrating exemplary steps for using data from a failed cyclic redundancy check (CRC) block to determine whether retransmission of data packets should occur, in accordance with an embodiment of the invention. Referring to FIG. 4, exemplary steps may begin at step 402. In step 404, a receiving station 152 may receive data packets from a sending station 102. In step 406, the processor 154 may compute the CRC value of the received data packets. A CRC may be computed for a group or block of bits referred to as frames. The computed CRC may then be appended to each frame for which a CRC is computed and the frame with the CRC may be transmitted. The appended CRC may be referred to as a frame check sequence (FCS).

In step 408, the frame check sequence may be extracted from the received information and a CRC value may be computed for the received data packet (CRC 2). In step 410, the calculated CRC value of the received data packet (CRC 2) may then be compared with the CRC value of the transmitted data packet or frame check sequence (CRC 1) and if there is a mismatch, then the received data packet may be in error. If the CRC of the received data packet (CRC 2) is equal to the frame check sequence or CRC value of the transmitted data packet (CRC 1), control passes to step 412. In step 412, a CRC pass status may be indicated for the received packet. Control then passes to end step 414.

If the CRC of the received data packet (CRC 2) is not equal to the frame check sequence or CRC of the transmitted data packet (CRC 1), control passes to step 416. In step 416, an error flag in the CRC field 308 may be set indicating a CRC fail status for the received data packet. In step 420, it may be determined whether a CRC pass status has been detected for a later received data packet or if a time out period has occurred. If a CRC pass status has been detected for a later received data packet or if a time out period has occurred, control passes to step 428. If a CRC pass status has not been detected for a later received data packet or if a time out period has not occurred, control passes to step 424. In step 424, the sequence number of the corresponding received data packet may be determined. In step 426, a sending station, for example, sending station 102 may be requested to resend the corresponding received data packet based on the determined sequence number. In step 428, a negative acknowledgement (NACK) packet may be communicated to the sending station 102 to request resending the corresponding received data packet. Control then passes to end step 414.

In accordance with an embodiment of the invention, a method and system for using data from a failed cyclic redundancy check (CRC) block to determine whether retransmission of data packets should occur may comprise at least one processor 154 that may be enabled to determine a sequence number of a received packet 200 with a failed cyclic redundancy check (CRC). The processor 154 may enable communication of a request to a sending station 102 to resend the received packet 200 based on the determined sequence number. The processor 154 may enable determining whether an error flag is set in the received packet 200 based on a calculated CRC value for the received packet 200. The processor 154 may enable detection of the received packet 200 with a failed CRC, if the error flag is set in the received packet 200. The processor 154 may enable communication of a negative acknowledgement (NACK) packet to request the sending station 102 to resend the received packet 200. The processor 154 may enable communication of the request prior to a time out period. The processor 154 may enable communication of the request prior to receiving a CRC pass from the sending station 102.

In an alternate embodiment of the invention, a NACK packet may be transmitted to the sending station 102 for each of the data packets received after receiving the data packet with the failed CRC.

The sending station 102 may be a wireless station or a wired station. The received packet 200 may be received at a wired receiver or a wireless receiver, for example, the receiving station 152. In accordance with an embodiment of the invention, the received packet 200 may be communicated and received at the data link layer. For example, there may be asynchronous transmission between the serial port of a computer or terminal and a modem, file transfer protocols, or synchronous transmission of contiguous blocks of data, with both sending and receiving stations synchronized to each other.

Another embodiment of the invention may provide a machine-readable storage, having stored thereon, a computer program having at least one code section executable by a machine, thereby causing the machine to perform the steps as described above for using data from a failed cyclic redundancy check (CRC) block to determine retransmission of data packets.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for handling data in a communication network, the method comprising:
determining a sequence number of a received packet with a failed cyclic redundancy check (CRC); and
communicating a request to a sending station to resend said received packet based on said determined sequence number.

2. The method according to claim 1, comprising determining whether an error flag is set in said received packet based on a calculated CRC value for said received packet.

3. The method according to claim 2, comprising if said error flag is set in said received packet, detecting said received packet with said failed CRC.

4. The method according to claim 1, comprising communicating a negative acknowledgement (NACK) packet to request said sending station to resend said received packet.

5. The method according to claim 1, wherein said request is communicated prior to a time out period.

6. The method according to claim 1, wherein said request is communicated prior to receiving a CRC pass from said sending station.

7. The method according to claim 1, wherein said sending station is a wireless station.

8. The method according to claim 1, wherein said sending station is a wired station.

9. The method according to claim 1, wherein said received packet is received at a wireless receiver.

10. The method according to claim 1, wherein said received packet is received at a wired receiver.

11. A system for handling data in a communication network, the system comprising:
at least one processor that enables determination of a sequence number of a received packet with a failed cyclic redundancy check (CRC); and
said at least one processor enables communication of a request to a sending station to resend said received packet based on said determined sequence number.

12. The system according to claim 11, wherein said at least one processor enables determining whether an error flag is set in said received packet based on a calculated CRC value for said received packet.

13. The system according to claim 12, wherein said at least one processor enables detection of said received packet with said failed CRC, if said error flag is set in said received packet.

14. The system according to claim 11, wherein said at least one processor enables communication of a negative acknowledgement (NACK) packet to request said sending station to resend said received packet.

15. The system according to claim 11, wherein said at least one processor enables communication of said request prior to a time out period.

16. The system according to claim 11, wherein said at least one processor enables communication of said request prior to receiving a CRC pass from said sending station.

17. The system according to claim 11, wherein said sending station is a wireless station.

18. The system according to claim 11, wherein said sending station is a wired station.

19. The system according to claim 11, wherein said received packet is received at a wireless receiver.

20. The system according to claim 11, wherein said received packet is received at a wired receiver.
